(19) United States
(12) Patent Application Publication
(10) Pub. No.: US 2006/0010359 A1
(43) Pub. Date: Jan. 12, 2006

(54) Method for testing electronic circuit units and test apparatus

(75) Inventors: Sven Boldt, Aschheim (DE); Erwin Thalmann, Villach (AT)

Correspondence Address: Maginot, Moore & Beck;Bank One Tower, Suite 3000, 111 Monument Circle, Indianapolis, IN, 46204, US

(73) Assignee: Infineon Technologies AG, Munchen (DE)

(21) Appl. No.: 11/131,902

(22) Filed: May 18, 2005

(30) Foreign Application Priority Data
May 18, 2004 (DE) 10 2004 024 668.8

(51) Int. Cl. G11C 29/00

(52) U.S. Cl. 714/718

(57) ABSTRACT

The invention provides a test apparatus for testing an electronic circuit unit to be tested. The test apparatus comprises a read-only memory for buffer-storing a test data stream read from the circuit unit to be tested in a manner dependent on a clock signal. The test apparatus further comprises a multiplexing unit for alternately outputting even data and odd data of the test data stream, and a driver device for driving the read-out test data stream to an output unit. Provision is made for a comparison device for bit by bit comparison of the even data and the odd data with one another and a blocking device for blocking the driver device if the read-out even data and the read-out odd data of the test data stream do not match.

The present invention generally relates to test systems designed for testing various circuit units to be tested. In particular, the present invention relates to test systems for testing DRAM memory modules (DRAM=Dynamic Random Access Memory) operated at double data rate DDR.

The present invention further relates to a method for testing an electronic circuit unit to be tested by means of a test apparatus, a test data stream comprising even data and odd data being read from the circuit unit to be tested in a manner dependent on a clock signal, the even data being read out upon a rising clock edge of the clock signal, and the odd data being read out upon a falling clock edge of the clock signal, the test data stream read from the circuit unit to be tested in a manner dependent on the clock signal being buffer-stored by means of a read-only memory, the even data and the odd data of the test data stream being output alternately by means of a multiplexing unit and the read-out test data stream being driven to an output unit by means of a driver device in order to obtain an output data stream.

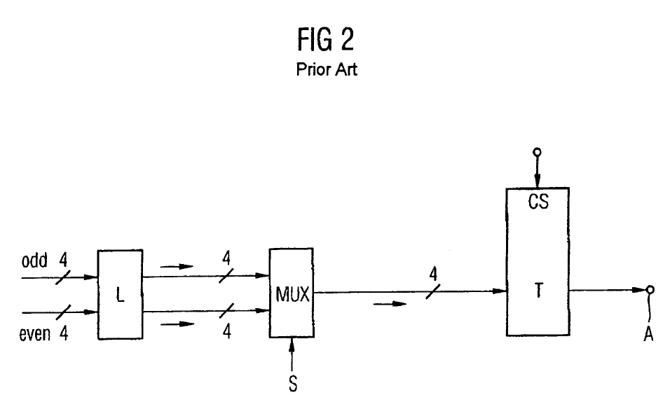

FIG. 2 shows a test apparatus for testing a circuit unit (not shown) to be tested, from which even data (even) and odd data (odd) are read out. The read-out data are buffer-stored in a read-only memory L and fed separately according to even and odd data to a multiplexing unit MUX via a data bus in each case 4 bits wide. On the basis of a control signal S fed to it, the multiplexing unit determines whether first the even data or the odd data and then the odd data or the even data, respectively, are read out and forwarded to a driver T.

During the test of the circuit unit to be tested by means of the test system, the driver T is activated by a “chip select” signal CS and drives the data output by the multiplexer MUX to an output terminal A.

When testing circuit units (electronic components, memory modules, chips, etc.) to be tested, it is very important to keep the test costs low. The test costs result directly from a test time per circuit unit to be tested which can be complied with during production steps for the electronic circuit unit. Recent architectures of circuit units to be tested use the so-called “double data rate”—DDR—in such a way that data are read into and respectively out of the circuit unit to be tested both upon the rising clock edge and upon the falling clock edge.

The requirement for increasing the rising operating frequencies entails the effect that customary test systems cannot process the high data rates when testing at double data rate. Although test systems have been developed which can be operated at the high operating frequencies of the circuit unit (chips) to be tested, these test systems have the disadvantage that even data and odd data cannot be read out in a single operating cycle. The temporal spacing of the “strobes”, i.e. the instants at which data are intended to be assessed in the case of reading, between even data and odd data is restricted in a disadvantageous manner.

In order to solve this problem, it has already been proposed, in the case of customary test systems, to perform double reading of the data written to the circuit unit to be tested. By way of example, firstly the even data are read out in a first read operation, while the odd data are read out in a subsequent, second read operation. This requires buffer-storing the corresponding data in the read-only memory L shown in FIG. 2 and outputting them alternately from said memory to the driver unit T with the aid of the multiplexer MUX controlled by means of a control signal S. This has the essential disadvantage for the testing of electronic circuit units to be tested out the double read-out—firstly even data and then odd data—increases the test time by 50%.

The described method according to the prior art accordingly leads to a test time that is increased by 30% relatively to the case in which writing to and reading from the circuit unit to be tested are effected at the double data rate.

In the case of writing to the circuit unit to be tested, conventional test systems are able to use a double data rate, while the test data stream has to be read out separately according to even data and odd data from the circuit unit to be tested. Since the writing-in and read-out operations require an approximately identical time duration, approximately 30% of the test time is allotted to writing in, a further 30% of the test time is allotted to reading out the even data and the remaining 30% to reading out the odd data.

Therefore, it is an object of the present invention to provide a test apparatus in the case of which a test time per circuit unit to be tested is reduced.

This object is achieved according to the invention by means of a test apparatus having the features of patent claim 1.

Furthermore, the object is achieved by means of a method specified in patent claim 5.

Further refinements of the invention emerge from the subclaims.

An essential concept of the invention consists in comparing with one another the even and odd data read from a read-only memory before said data are output via a driver device. It is presupposed in this case that the even data and the odd data of a test data stream are identical in the case of an operation of writing to the electronic circuit unit to be tested. If the circuit unit to be tested functions in a manner free of errors, then the read-out even data and the read-out odd data of the read-out test data stream must also match one another. The heart of the invention consists in an internal data comparison of the even data and the odd data in such a way that an error indication state is generated internally and forwarded toward the outside if the even data and the odd data of the test data stream do not match.

In this way, the test apparatus according to the present invention affords the advantage that the data can be read out at a high data rate, i.e. the same data rate as during writing in, i.e. the double data rate DDR. In order to evaluate the functionality of a circuit unit to be tested, it is merely necessary to ascertain whether the latter functions without any-errors for all data read out, i.e. the even data and the odd data. If an error state occurs even just a single time during the read-out of the even and odd data of the test data stream, then this means that the circuit unit to be tested has an error and cannot be used. In an advantageous manner, a driver device for outputting the test data stream from the circuit unit to be tested is then blocked by means of a blocking signal if an error state of this type is ascertained by means of the internal data comparison of the even data and the odd data of the test data stream. A switch-off or blocking of the driver device for outputting an output data stream that corresponds to the read-out test data stream in the case of error-free functioning of the circuit unit to be tested indicates to the test system that an error has occurred in the circuit unit to be tested.

In this way, the test apparatus according to the invention enables a simple “pass-fail” information item for the entire test operation.

The test apparatus according to the invention for testing an electronic circuit unit to be tested essentially has:
a) a read-only memory for buffer-storing a test data stream read from the circuit unit to be tested in a manner dependent on a clock signal, said test data stream comprising even data which have been read out upon a rising clock edge of the clock signal, and odd data which have been read out upon a falling clock edge of the clock signal;
b) a multiplexing unit for alternately outputting the even data and the odd data of the test data stream; and
c) a driver device for driving the read-out test data stream to an output unit in order to obtain an output data stream, provision being made of a comparison device for bit by bit comparison of the even data and the odd data of the test data stream with one another and for outputting corresponding comparison signals and a blocking device for blocking the driver device if the read-out even data and the read-out odd data of the test data stream do not match.

Furthermore, the method according to the invention for testing an electronic circuit unit to be tested essentially has the following steps:
a) read-out of a test data stream comprising even data and odd data from the circuit unit to be tested in a manner dependent on a clock signal, the even data being read out upon a rising clock edge of the clock signal, and the odd data being read out upon a falling clock edge of the clock signal;
b) buffer-storage of the test data stream read from the circuit unit to be tested in a manner dependent on the clock signal by means of a read-only memory;
c) alternate outputting of the even data and the odd data of the test data stream by means of a multiplexing unit; and
d) driving of the read-out test data stream to an output unit by means of a driver device in order to obtain an output data stream, the even data and the odd data of the test data stream being compared bit by bit with one another and corresponding comparison signals being output by means of a comparison device, and the driver device being blocked when the read-out even data and the read-out odd data of the test data stream do not match.

Advantageous developments and improvements of the respective subject matter of the invention are found in the subclaims.

In accordance with one preferred development of the present invention, the blocking device for blocking the driver device if the read-out even data and the read-out odd data of the test data stream do not match comprises a combination unit for logic combination of the comparison signals output from the comparison device and for outputting a corresponding combination signal and a memory unit for storing an error indication state and for outputting a blocking signal for the driver device if at least one comparison—carried out in the comparison device—of the even data and the odd data of the test data stream indicates no matching of the even data and the odd data.

In accordance with a further preferred development of the present invention, the combination unit of the blocking device is designed as an OR gate.

In accordance with yet another preferred development of the present invention, the comparison device for bit by bit comparison of the even data and the odd data of the test data stream with one another and for outputting corresponding comparison signals for each bit is formed by a respective EXCLUSIVE-OR gate.

In accordance with yet another preferred development of the present invention, the error indication state stored in the memory unit cannot be reset after at least one comparison—carried out in the comparison device—of the even data and the odd data of the test data stream has indicated no matching of the even data and the odd data.

An exemplary embodiment of the invention is illustrated in the drawing and is explained in more detail in the description below.

In the drawings:

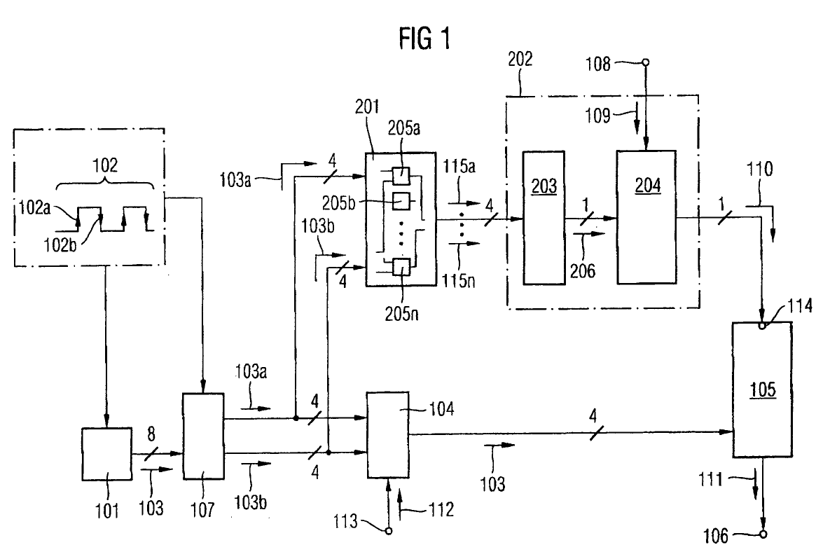

FIG. 1 shows a schematic block diagram of a test apparatus in accordance with a preferred exemplary embodiment of the present invention; and

FIG. 2 shows a conventional test apparatus.

In the figures, identical reference symbols designate identical or functionally identical components or steps.

In the test apparatus shown in FIG. 1, a clock signal 102 having rising clock edges 102a and falling clock edges 102b is applied to a circuit unit 101 to be tested. In the preferred exemplary embodiment of the present invention that is shown, an 8 bit wide test data stream 103 based on the DDR architecture (double data rate) is read from the circuit unit 101 to be tested.

The clock signal 102 is likewise applied to the test apparatus, as indicated by an arrow toward a read-only memory 107. The test data stream 103 read from the circuit unit 101 to be tested is buffer-stored in the read-only memory 107, in such a way that it is possible for even data that are read out upon a rising clock edge 102a of the clock signal 102 and odd data 103b that are read out upon a falling clock edge 102b of the clock signal 102 to be provided separately from one another.

The even data 103a and odd data 103b of the test data stream 103 that are provided separately from one another are output in each case on a data bus 4 bits wide. The even data 103a and the odd data 103b of the test data stream 103 are fed both to a multiplexing unit 104 and to a comparison device 201, separately via a 4 bit wide data bus for the even data 103a and a 4 bit wide data bus for the odd data 103b. By means of the multiplexing unit 104, the even data 103a and the odd data 103b of the test data stream 103 can be multiplexed and output alternately to a driver device 105. The multiplexing unit 104 operates in a manner dependent on a multiplexing unit drive signal, which is fed in via a control input and the provision of which is familiar to the person skilled in the art for test apparatuses, for which reason it is not described in any greater detail here.

The even data 103a and odd data 103b fed to the comparison device 201 are compared bit by bit with one another. For this purpose, in accordance with the preferred exemplary embodiment of the present invention, EXCLUSIVE-OR gates 205a-205n are provided in the comparison device 201. The number of EXCLUSIVE-OR gates corresponds to the bit width respectively of the data bus for the even data 103a and of the data bus for the odd data 103b and is 4 in the preferred exemplary embodiment of the present invention.

The four EXCLUSIVE-OR gates used in the comparison device 201 indicate a logic “1” level when the even data 103a do not match the odd data 103b of the test data stream 103, i.e. when the circuit unit 101 to be tested exhibits an erroneous function. The EXCLUSIVE-OR combination in the EXCLUSIVE-OR gates 205a-205n thus leads to comparison signals 115a-115m for each EXCLUSIVE-OR gate. The four comparison signals 115a-115d that result here are fed to a blocking device 202, in which they are processed further.

The blocking device 202 serves for outputting a blocking signal 110 when an erroneous operation of the circuit unit 101 to be tested is ascertained. An erroneous operation of the circuit unit 101 to be tested is ascertained—as explained above—when, after identical even data 103a and odd data 103b have been written to the circuit unit to be tested, a difference in the even data 103a and the odd data 103b of the test data stream 103 is ascertained during a read-out. If the even data 103a and the odd data 103b of the test data stream 103 match one another throughout the test, then the blocking unit 202 outputs an activation signal 110 for the driver device 105. The activation signal (or blocking signal) 110 is fed to an activation input 114 of the driver device 105.

The activation input 114 corresponds to a “Chip-Select” input of the driver device 105, by means of which the driver device is activated for operation. If the driver device is activated by the activation signal 110, this means that the test data stream 103 fed to the driver device 105 from the multiplexing unit 104 is afforded as an output data stream 111 to an output unit 106.

If an error of the circuit unit 101 to be tested, said error being ascertained by a lack of matching between the even data 103a and the odd data 103b of the test data stream 103, is detected—i.e. if an error indication state F is brought about—, then the blocking device 202 transmits a blocking signal 110 to the driver device 105, which has the effect that the output of the driver device undergoes transition to a high-impedance level (tristate). Such a “tristate” level at the output unit 106 of the driver device 105 indicates to the test system (test apparatus) that an erroneous function of the circuit unit 101 to be tested is present.

After a presence of an error indication state F, the test system recognizes that the circuit unit 101 to be tested has an error and cannot be used further. The test of the circuit unit 101 to be tested can thus be terminated in an advantageous manner, thereby reducing a test time and saving test costs.

The operation of the blocking device 202 will be explained below. The blocking device 202 has a combination unit 203 and a memory unit 204 connected to the combination unit. The combination unit 202 effects a logic combination of the comparison signals 115a-115n read out bit by bit from the comparison device 201 and an outputting of a corresponding combination signal 206 to the memory unit 204.

The combination unit 203 is preferably provided by an OR gate in such a way that an OR combination of the comparison signals fed by the comparison device is made possible. This means that when one of the comparison signals 115a-115n (four comparison signals 115a-115d are present in the preferred exemplary embodiment) has a logic “1” level, then a logic “1” level is output as the combination signal 206 from the combination unit 203. The combination signal has a bit width of 1. The memory unit 204 is correspondingly formed as a 1-bit memory (latch). The 1-bit memory can be switched on/activated/set and reset by a test mode signal 109 fed by means of a test mode input unit 108. If the combination signal 206 is at a logic “1” level, the memory unit 204 is set to logic “1” and maintains this state until it is reset by a test mode signal 109.

An output signal of the memory unit 204 that is at a logic “1” level represents a blocking signal 110 for the driver device 105. Said blocking signal 110 blocks the driver device 105 in such a way that an error state identified by a high-impedance output is obtained. The table below shows the combination of the even data 103a with the odd data 103b of the test data stream 103 to form an output data stream 111.

TABLE 1

| Even data | Odd data | Output data stream |
|---|---|---|
| 103a | 103b | 111 |
| 0 | 0 | 0 |
| 0 | 1 | F |
| 1 | 0 | F |
| 1 | 1 | 1 |

In this case, the test data stream 103 is driven unchanged to the output unit 106 as an output data stream 111 by means of the driver unit 105 if the even data 103a and the odd data 103b match, i.e. these are simultaneously in the same way at a “0” level (first row in table 1) or at a “1” level (last row in table 1).

In the other two cases, the even data 103a do not match the odd data 103b, indicated in the middle two rows of table 1. If the even data 103a are at a “0” level, while the odd data 103b are simultaneously at a “1” level, then an error indication state F is brought about.

An error indication state “F” is brought about in the same way when the even data 103a are at a “1” level, while the odd data are at a “0” level.

With regard to the conventional test apparatus for testing circuit units to be tested as illustrated in FIG. 2, reference is made to the introduction to the description.

Although the present invention has been described above on the basis of preferred exemplary embodiments, it is not restricted thereto, but rather can be modified in diverse ways.

Moreover, the invention is not restricted to the application possibilities mentioned.

1-9. (canceled)

10. A test apparatus for testing an electronic circuit unit to be tested, the test apparatus comprising:
a) a read-only memory operable to buffer-store a test data stream read from the circuit unit to be tested in a manner dependent on a clock signal, said test data stream including
i) even data which are read out upon a rising clock edge of the clock signal, and
ii) odd data which are read out upon a falling clock edge of the clock signal;
b) a multiplexing unit operable to alternately output the even data and the odd data of the test data stream;
c) a driver device operable to drive the read-out test data stream to an output unit in order to obtain an output data stream;
d) a comparison device operable to perform a bit by bit comparison of the even data and the odd data of the test data stream, the comparison device further operable to output corresponding comparison signals for each bit by bit comparison; and
e) a blocking device operable to block the driver device if the read-out even data and the read-out odd data of the test data stream do not match.

11. The apparatus of claim 10 wherein the blocking device comprises (i) a combination unit operable to perform a logic combination of the comparison signals output from the comparison device and to output a corresponding combination signal; and (ii) a memory unit operable to store an error indication state and output a blocking signal to the driver device if at least one comparison made by the comparison device of the even data and the odd data of the test data stream indicates that the even data and the odd data do not match.

12. The apparatus of claim 11 wherein the combination unit of the blocking device comprises an OR gate.

13. The apparatus of claim 10 wherein the comparison device comprises a plurality of EXCLUSIVE-OR gates.

14. A method for testing an electronic circuit unit to be tested by means of a test apparatus, the method comprising the following steps:
a) reading a test data stream comprising even data and odd data from the circuit unit to be tested;
b) buffer-storing the test data stream read from the circuit unit to be tested;
c) alternately outputting the even data and the odd data of the test data stream to a driver device;
d) driving the test data stream to an output unit as an output data stream using the driver device;
e) comparing the even data and the odd data of the test data stream on a bit by bit basis and outputting corresponding comparison signals; and
f) blocking the driver device if the even data and the odd data of the test data stream do not match.

15. The method of claim 14 wherein step e) includes the following substeps:
i) performing a logic combination of the comparison signals and outputting a corresponding combination signal; and
ii) storing an error indication state and outputting a blocking signal to the driver device if the even data and the odd data do not match.

16. The method of claim 15 wherein the step of performing a logic combination of the comparison signals comprises performing an OR combination of the comparison signals.

17. The method of claim 14 wherein the step of comparing the even data and the odd data of the test data stream on a bit by bit basis and outputting corresponding comparison signals includes a bit by bit EXCLUSIVE-OR combination of the even data with the odd data.

18. The method of claim 15 wherein the stored error indication state cannot be reset after at least one comparison of the even data and the odd data do not match.

19. The method of claim 14 wherein the test data stream comprising even data and odd data from the circuit unit to be tested is read in a manner dependent on a clock signal.

20. The method of claim 19 wherein the even data is read upon a rising clock edge of the clock signal and the odd data is read upon a falling clock edge of the clock signal.

21. The method of claim 14 wherein the test data stream read from the circuit unit to be tested is buffer-stored in a read-only memory.

22. The method of claim 14 wherein a multiplexer is used to perform the step of alternately outputting the even data and the odd data of the test data stream.

23. A test apparatus for testing an electronic circuit unit to be tested, the test apparatus comprising:
a) a read-only memory operable to buffer-store a test data stream read from the circuit unit to be tested, the test data stream comprising even data and odd data;
b) a multiplexer operable to alternately output the even data and the odd data of the test data stream;
c) a driver connected to the multiplexer, the driver operable to drive the read test data stream to an output;
d) a comparator operable to perform a bit by bit comparison of the even data and the odd data of the test data stream, the comparator further operable to output corresponding comparison signals for each bit by bit comparison; and
e) a blocking device operable to block the driver if the read even data and the read odd data of the test data stream do not match.

24. The device of claim 23 wherein the test data stream is read in a manner dependent on a clock signal.

25. The device of claim 24 wherein the even data are read upon a rising clock edge of the clock signal, and the odd data are read upon a falling clock edge of the clock signal.

26. The device of claim 23 wherein the blocking device comprises (i) a combination unit operable to perform a logic combination of the comparison signals output from the comparator and to output a corresponding combination signal; and (ii) a memory unit operable to store an error indication state and output a blocking signal to the driver if at least one comparison made by the comparator of the even data and the odd data of the test data stream indicates that the even data and the odd data do not match.

27. The apparatus of claim 26 wherein the combination unit of the blocking device comprises an OR gate.

28. The apparatus of claim 23 wherein the comparator comprises a plurality of EXCLUSIVE-OR gates.

29. The apparatus of claim 23 wherein the comparator is connected to the multiplexer.
